(19) United States
(12) Patent Application Publication
(10) Pub. No.: US 2026/0117373 A1
(43) Pub. Date: Apr. 30, 2026

(54) SUBSTRATE PROCESSING APPARATUS AND METHOD

(71) Applicant: Picosun Oy, Espoo (FI)

(72) Inventors: Mikko NÄSI, Espoo (FI); Tom BLOMBERG, Espoo (FI); Timo VÄHÄ-OJALA, Espoo (FI)

(21) Appl. No.: 18/931,096

(22) Filed: Oct. 30, 2024

(51) Int. Cl. C23C 16/44; C23C 16/455

(52) U.S. Cl. CPC C23C 16/4412; C23C 16/45546

(57) ABSTRACT

A substrate processing apparatus (100) and a method, comprising a reaction chamber (110) for accommodating one or more substrates (120) for processing, wherein the reaction chamber walls comprise a first wall (W1), second wall W2 located opposite to the first wall (W1), and one or more side walls connecting the first wall (W1) and the second wall (W2), an injection manifold (130) attached to the first wall (W1) to feed precursor flow (Fp) to the reaction chamber (110) through an entrance opening (160) in the first wall (W1), and two exhaust ports, a first exhaust port (150a) and a second exhaust port (150b), arranged to at least one of the one or more the side walls (SW1, SW2, SW3, SW4) to remove fluid from the reaction chamber (110).

### TECHNICAL FIELD

The present disclosure generally relates to an apparatus and method for substrate processing. The disclosure relates particularly, though not exclusively, to thin-film deposition, such as an atomic layer deposition.

### BACKGROUND

This section illustrates useful background information without admission of any technique described herein representative of the state of the art.

Substrate processing techniques, such as ALD and chemical vapor deposition (CVD), enable precise and high-quality surface modification and deposition processes. For example, in ALD sequential self-saturating reactions of precursor chemicals are used to grow pinhole-free thin films on substrates.

Uniform flow and distribution of reaction precursors within a substrate processing apparatus is desirable to ensure optimal substrate processing quality. Uneven reaction conditions may result in processing defects and waste of precursor chemicals.

Hence, a need exists for improved substrate processing apparatuses.

### SUMMARY

The appended claims define the scope of protection. Any examples and technical descriptions of apparatuses, products and/or methods in the description and/or drawings not covered by the claims are presented not as embodiments of the invention but as background art or examples useful for understanding the invention.

It is an object of the present invention to provide an improved substrate processing apparatus, or at least provide an alternative to existing solutions. Especially, it is an aim to provide a substrate deposition apparatus with improved deposition quality while ensuring efficient processing.

According to a first example aspect there is provided a substrate processing apparatus, comprising:
a reaction chamber for accommodating one or more substrates for processing, wherein the reaction chamber walls comprise a first wall, second wall located opposite to the first wall, and one or more side walls connecting the first wall and the second wall;
an injection manifold attached to (a section of) the first wall to feed precursor flow to the reaction chamber through an entrance opening in the first wall; and
two exhaust ports, a first exhaust port and a second exhaust port, arranged to at least one (section) of the one or more side walls to remove fluid from the reaction chamber.

In certain embodiments, the first wall, second wall and one or more side walls are sections of the one or more walls configured to form the reaction chamber walls. In certain embodiments, the first wall, second wall and one or more side walls are planar. In certain embodiments, at least one of the first wall, second wall and one or more side walls is planar. In certain embodiments, the first wall, second wall and/or one or more side walls comprise at least one curved wall. In certain embodiments, the first wall, second wall and/or one or more side walls are curved walls. In certain embodiments, the first wall, second wall and one or more side walls are respective parts or sections of one or more curved reaction chamber walls.

In certain embodiments, the two exhaust ports are configured to extend at least partially across the one or more side wall or walls (along the surface of the one or more side walls) to which the exhaust ports are arranged. In certain embodiments, the two exhaust ports are configured to (fully) extend across the respective one or more side walls to a dimension of the reaction chamber. That is, the shape of the two exhaust port openings at the one or more side walls is an elongated shape in certain embodiments.

In certain embodiments, the two exhaust ports are configured to extend at least partially across the one or more side walls in a direction which is perpendicular to a plane defined by the first wall. In certain embodiments, the two exhaust ports are configured to extend at least partially across the one or more side walls in a direction which is perpendicular to a plane defined by (a cross section of) the entrance opening.

In certain embodiments, the two exhaust ports are configured to extend at least partially across the one or more side walls in a direction which is parallel to a plane defined by the first wall. In certain embodiments, the two exhaust ports are configured to extend at least partially across the one or more side walls in a direction which is parallel to a plane defined by (a cross section of) the entrance opening.

In certain embodiments, the first exhaust port is arranged to a first side wall (or a first side wall section), and the second exhaust port is arranged to a second side wall (or a second side wall section), wherein the first side wall (or the first side wall section) and the second side wall (or the second side wall section) are opposite to each other and located at opposite sides of the reaction chamber.

In certain embodiments, the two exhaust ports are arranged adjacent to each other at one (section) of the one or more side walls. In certain embodiments, the two exhaust ports are arranged adjacent to each other at the first side wall.

In certain embodiments, the two exhaust ports are arranged to at least one of the one or more side walls immediately adjacent to the first wall. In certain embodiments, the two exhaust ports are arranged to reaction chamber walls adjacent to the first wall. In certain embodiments, the two exhaust ports are arranged to the one or more side walls adjacent to the first wall.

In certain embodiments, the two exhaust ports are arranged parallel to each other. In certain embodiments, planes defined by the two exhaust ports are parallel to each other.

In certain embodiments, the two exhaust ports comprise a perforated structure. Advantageously, fluid flow through the exhaust ports may be better controlled.

In certain embodiments, the entrance opening is configured to extend across the first wall (along the surface of the first wall) in a predetermined direction to a dimension of the reaction chamber. For instance, in certain embodiments the entrance opening may be reaction chamber wide. Advantageously, precursor flow may be more uniformly delivered to the reaction chamber across the entire width of the reaction chamber.

In certain embodiments, the entrance opening is configured to extend (to a dimension of the reaction chamber) across the first wall in a direction which is perpendicular to a direction in which the two exhaust ports at least partially extend across the one or more side walls. In certain embodiments, the entrance opening is configured to extend across the first wall in a direction which is perpendicular to a plane defined by the first side wall.

In certain embodiments, the entrance opening is configured to extend to a dimension of the reaction chamber across the first wall in a direction which is parallel to a direction in which the two exhaust ports at least partially extend across the one or more side walls. In certain embodiments, the entrance opening is configured to extend across the first wall in a direction which is parallel to a plane defined by the first side wall.

In certain embodiments, the apparatus is configured to accommodate one or more individual substrates within the reaction chamber (for substrate processing). In certain embodiments, the individual substrates are laterally separated from each other within the reaction chamber.

In certain embodiments, the apparatus is configured to accommodate one or more stacks of substrates within the reaction chamber (for substrate processing).

In certain embodiments, the apparatus is configured to accommodate the one or more stacks of substrates aligned such that the height direction of the one or more stacks of substrates is aligned perpendicular to a direction in which the two exhaust ports extend at least partially across the one or more side wall or walls to which the two exhaust ports are arranged.

In certain embodiments, the apparatus is configured to accommodate the one or more stacks of substrates aligned such that the height direction of the one or more stacks of substrates is aligned parallel to a direction in which the two exhaust ports extend at least partially across the one or more side wall or walls to which the two exhaust ports are arranged.

In certain embodiments, the height direction of the one or more stacks of substrates is aligned parallel to a plane defined by the entrance opening. In certain embodiments, the height direction of one or more stacks of substrates is aligned parallel to a direction in which the entrance opening extends across the first wall.

In certain embodiments, the height direction of the one or more stacks of substrates is aligned perpendicular to a plane defined by the entrance opening. In certain embodiments, the height direction of one or more stacks of substrates is aligned perpendicular to a direction in which the entrance opening extends across the first wall.

In certain embodiments, the injection manifold comprises a first expansion region and second expansion region configured to receive first fluid flow and second fluid flow, respectively, to the injection manifold.

In certain embodiments, the injection manifold is configured to combine the first fluid flow and the second fluid flow within the injection manifold to form the precursor flow.

In certain embodiments, the first expansion region and second expansion region are configured to direct the first fluid flow and the second fluid flow, respectively, to propagate substantially towards each other before forming the precursor flow.

In certain embodiments, the first and second expansion regions are configured to expand the first fluid flow and the second fluid flow, respectively, within the injection manifold to a dimension of the entrance opening extending across the first wall of the reaction chamber before forming the precursor flow.

In certain embodiments, the injection manifold is configured to (gradually) turn the first fluid flow and the second fluid flow substantially 90 degrees towards the reaction chamber within the injection manifold before feeding said fluid flows as the precursor flow to the reaction chamber.

In certain embodiments, the first expansion region and second expansion region are mirror images of each other.

In certain embodiments, the injection manifold is configured to feed the precursor flow as (substantially) laminar flow to the reaction chamber.

In certain embodiments, the apparatus comprises two injection manifolds, a first injection manifold and a second injection manifold, to feed precursor flow to the reaction chamber. In certain embodiments, the first injection manifold is attached to the first wall and the second injection manifold is attached to the second wall located opposite to the first injection manifold and the first wall (at the opposite side of the reaction chamber).

According to a second example aspect there is provided a method for processing substrates, comprising:
accommodating one or more substrates within a reaction chamber, reaction chamber walls comprising a first wall, second wall located opposite to the first wall, and one or more side walls connecting the first wall and the second wall;
feeding precursor flow to the reaction chamber for substrate processing by an injection manifold (attached to the first wall or a section of the first wall) through an entrance opening in the first wall; and
removing fluid from the reaction chamber through two exhaust ports, a first exhaust port and a second exhaust port, arranged to at least one (section) of the one or more side walls.

In certain embodiments, the first exhaust port is arranged to (a section of) the first side wall and the second exhaust port is arranged to (a section of) the second side wall, wherein (the section of) the first side wall and (the section) of the second side wall are opposite to each other and located at opposite sides of the reaction chamber.

In certain embodiments, the two exhaust ports (the first exhaust port and the second exhaust port) are arranged adjacent to each other at one (section) of the one or more side walls. In certain embodiments, the two exhaust ports are arranged adjacent to each other to (a section of) the first side wall.

In certain embodiments, the two exhaust ports are arranged to at least one of the one or more side walls immediately adjacent to the first wall.

In certain embodiments, the method further comprises:
receiving first fluid flow and second fluid flow to the injection manifold and combining the first fluid flow and second fluid flow within the injection manifold to form the precursor flow.

In certain embodiments, the method comprises:
expanding the first fluid flow and the second fluid flow within the injection manifold to a dimension of an entrance opening extending across the first wall of the reaction chamber before combining said flows to form the precursor flow.

In certain embodiments, the method comprises:
feeding the precursor flow to the reaction chamber as laminar flow.

In certain embodiments, the method comprises:
providing two injection manifolds, first injection manifold and second injection manifold, wherein the first injection manifold is attached to (a section of) the first wall and the second injection manifold is attached to (a section of) the second wall located opposite to the first injection manifold and (the section of) the first wall; and
feeding precursor flow the reaction chamber by the two injection manifolds.

In certain embodiments, the method comprises:
processing the one or more substrates with alternating self-limiting surface reactions within the reaction chamber.

In certain embodiments, accommodating the one or more substrates comprises:
accommodating one or more individual substrates within the reaction chamber. In certain embodiments, the one or more individual substrates are laterally separated from each other within the reaction chamber.

In certain embodiments, accommodating the one or more substrates comprises:
accommodating one or more stacks of substrates within the reaction chamber.

In certain embodiments, two or more stacks are aligned parallel to each other (having their axes in height direction of the stacks parallel to each other).

In certain embodiments, the method comprises aligning the height direction of the one or more stack of substrates parallel to a direction in which the two exhaust ports extend at least partially across the one or more side walls to which the two exhaust ports are arranged. In certain embodiments, the method comprises aligning the height direction of the one or more stack of substrates perpendicular to a direction in which the two exhaust ports extend at least partially across the one or more side walls to which the two exhaust ports are arranged.

In certain embodiments, the method comprises aligning the height direction of the one or more stack of substrates parallel to a direction in which the entrance opening of the reaction chamber extends across the first wall.

In certain embodiments, the method comprises aligning the height direction of the one or more stack of substrates perpendicular to a direction in which an entrance opening of the reaction chamber extends across the first wall.

Different non-binding example aspects and embodiments have been illustrated in the foregoing. The embodiments in the foregoing are used merely to explain selected aspects or steps that may be utilized in different implementations. Some embodiments may be presented only with reference to certain example aspects. It should be appreciated that corresponding embodiments may apply to other example aspects as well.

### BRIEF DESCRIPTION OF THE FIGURES

Some example embodiments will be described with reference to the accompanying figures, in which:

FIG. 1a and b schematically show cross-sectional side view and top view, respectively, of an apparatus for processing a single substrate according to certain embodiments;

FIGS. 2a and 2b schematically show cross-sectional side view and top view, respectively, of an apparatus for processing at least two substrates according to certain embodiments;

FIGS. 3a and 3b schematically show cross-sectional side view and top view, respectively, of an apparatus for processing at least two stacks of substrates according to certain embodiments;

FIGS. 4a-5b schematically show cross-sectional side views and top views, respectively, of apparatuses for processing a stack of substrates according to certain embodiments;

FIGS. 6a and 6b schematically show cross-sectional side view and top view, respectively, of an apparatus for processing two stacks of substrates according to certain other embodiments;

FIGS. 7a and 7b schematically show cross-sectional side view and top view, respectively, of another apparatus for processing a stack of substrates according to certain embodiments; FIGS. 8a and 8b schematically show cross-sectional side view and top view, respectively, of another apparatus for processing two stacks of substrates according to certain embodiments;

FIGS. 9a-10b schematically show cross-sectional side views and top views, respectively, of yet another apparatuses for processing a stack of substrates according to certain embodiments;

FIGS. 11a-12b schematically show cross-sectional side views and top views, respectively, of yet another apparatuses for processing one or more substrates according to certain alternative embodiments;

FIGS. 13a-13b schematically show cross-sectional side view and top view of an yet another apparatus according to certain embodiments; and

FIG. 14 shows a flow chart of a method according to certain embodiments.

### DETAILED DESCRIPTION

In the following description, like reference signs denote like elements or steps.

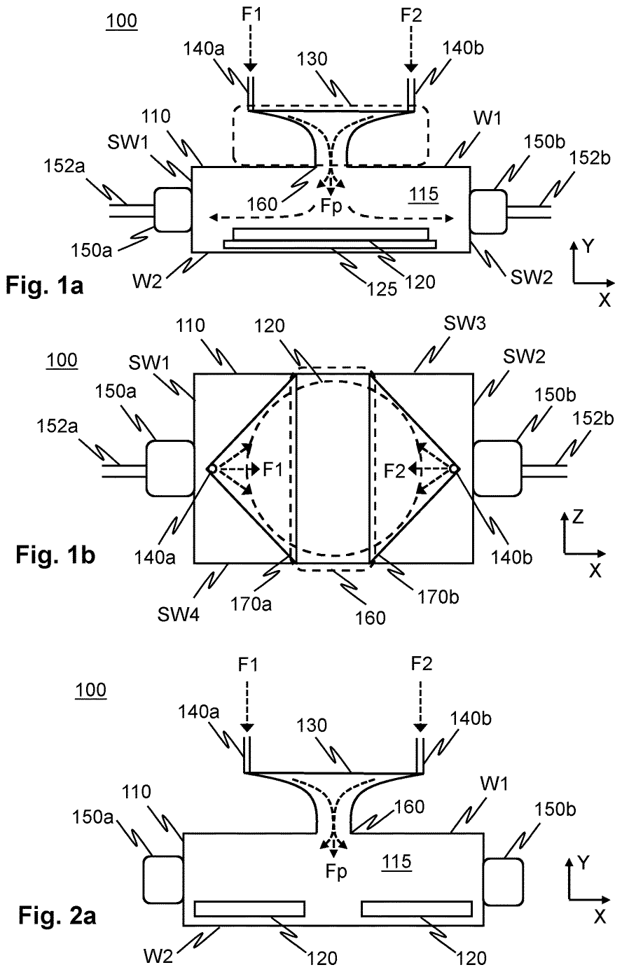

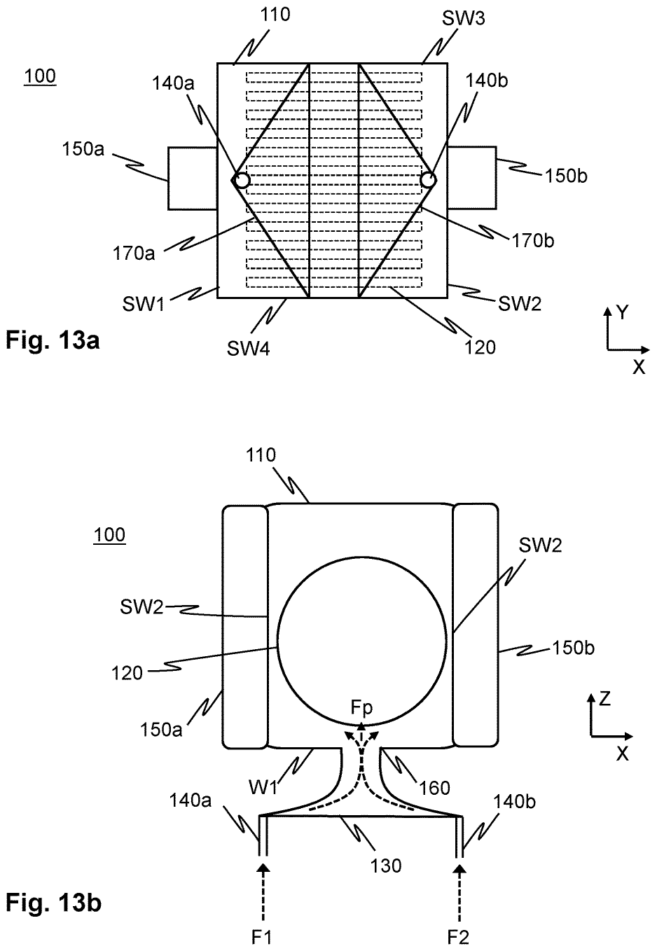

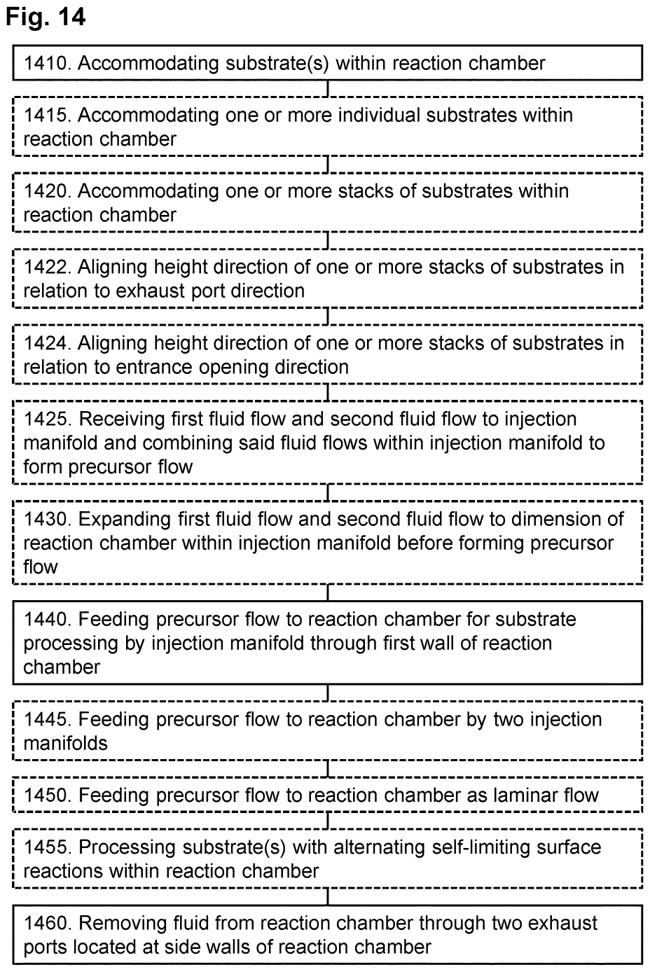

In certain embodiments described herein, is provided a substrate processing apparatus 100, and a corresponding method for processing substrates 120. Exemplary substrate processing apparatuses 100 according to certain embodiments are shown in FIGS. 1a-13b. An exemplary method according to certain embodiments is depicted in FIG. 14.

As used herein, fluid may refer to a liquid or a gas, or a combination thereof. However, in the context of the present disclosure, fluids are preferably gaseous substances, comprising precursor chemical(s), (inert) carrier gas(es) and purging gas(es) used in substrate processing.

In the context of the present disclosure, laminar flow, or streamline flow, is defined as a flow void of turbulence (without turbulent velocity fluctuations). In laminar flow, fluid layers/streams slide in parallel in an absence of vorticity, swirls or currents and the laminar flow constantly progresses towards one general direction. However, the laminar flow may expand laterally, curve or be re-directed, as long as turbulence is avoided and the flow constantly proceeds towards a predetermined direction.

Substrate processing apparatuses, or surface deposition apparatuses, in the context of the present disclosure are configured to exploit principles of vapor-deposition based techniques. In preferred embodiments, the substrate processing apparatus is an ALD apparatus. As used herein, the term ALD comprises all applicable ALD based techniques and any equivalent or closely related technologies, such as, for example the following ALD sub-types: MLD (Molecular Layer Deposition), plasma-assisted ALD, such as PEALD (Plasma Enhanced Atomic Layer Deposition) and photon-enhanced Atomic Layer Deposition (known also as flash enhanced ALD).

The skilled person is aware of the principles of ALD. In ALD, at least one substrate is typically exposed to temporally separated precursor pulses in a reaction vessel to deposit material on the substrate surfaces by sequential self-saturating surface reactions.

In further embodiments, the substrate processing apparatus is applied to other deposition technologies, such as Physical Vapor Deposition (PVD) and for Plasma-Enhanced Chemical Vapor Deposition (PECVD) processes.

In certain embodiments, the substrate processing apparatus is an atomic layer etching (ALE) apparatus.

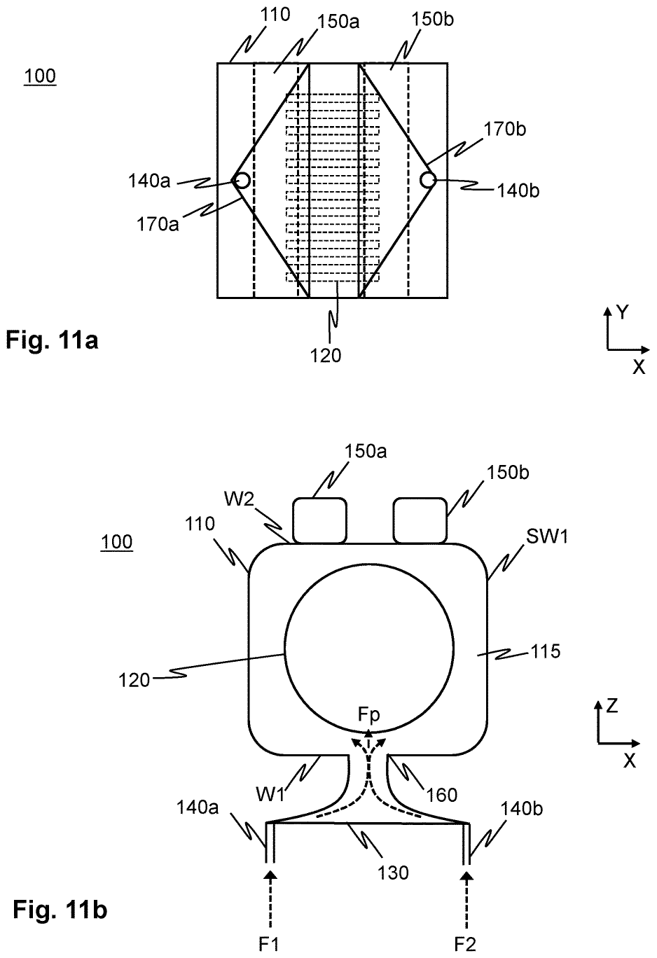

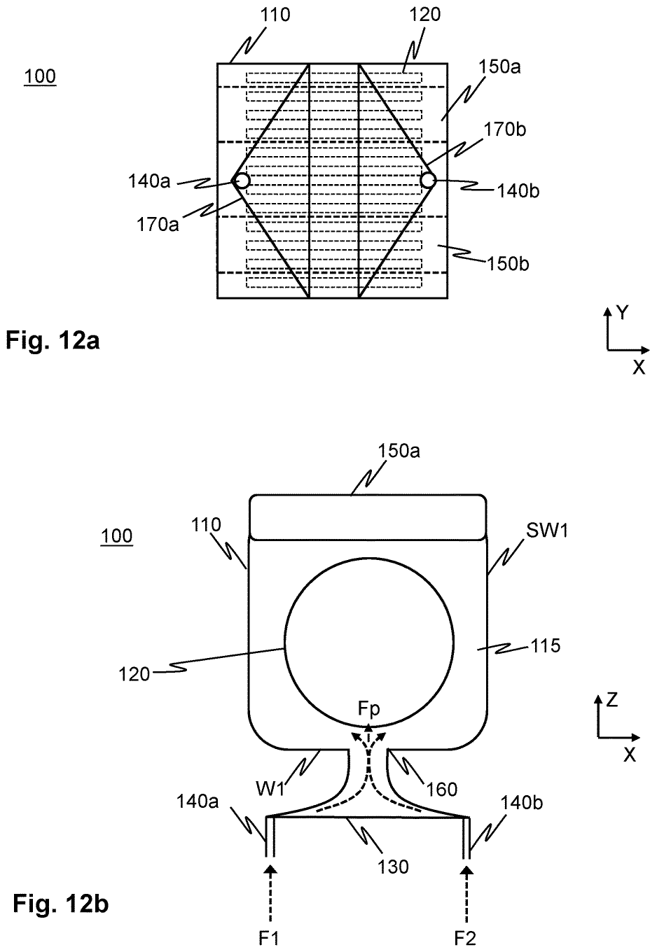

The dashed arrows in the drawings depict fluid flows and their general flow directions to and within the apparatus 100. The dashed circle(s) and rectangle(s) within the reaction volume in FIGS. 1b, 2b, 3b, 4a, 5a, 6a, 7a, 8a, 9a, 10a, 11a, 12a and 13a depict substrates located behind and viewed through the injection manifold 130 and first wall W1. Furthermore, dashed larger rectangles extending across reaction volume in FIGS. 11a and 12a depict exhaust ports arranged to the second wall W2 away from the viewer (behind the substrates at the back wall of the apparatus).

A direction indicator with X, Y, and Z axes is included in FIGS. 1a-13b for clarity and reader's convenience.

The apparatus 100 comprises a reaction chamber 110 for accommodating one or more substrates 120 for processing. The (inner) walls of the reaction chamber 110 define a reaction volume 115 within the reaction chamber 100. In certain embodiments, the reaction chamber walls comprise a first wall W1. In certain embodiments, the reaction chamber walls comprise a second wall W2 opposite to the first wall W1. In other words, the second wall W2 and first wall W1 are located on opposite sides of the reaction chamber 110 and on opposite sides of substrate(s) accommodated within the reaction chamber 110 in certain embodiments. In certain embodiments, the first wall W1 and the second wall W2 are parallel to each other.

In certain embodiments, the reaction chamber walls comprise one or more side walls SW1, SW2, SW3, SW4. In certain embodiments, the one or more side walls SW1, SW2, SW3, SW4 are arranged between the first wall W1 and the second wall W2. In certain embodiments the one or more side walls SW1, SW2, SW3, SW4 are configured to connect the first wall W1 and the second wall (to each other).

In certain embodiments, the reaction chamber 110 is defined by the first wall W1, the second wall W2, and the one or more side walls SW1, SW2, SW3, SW4. In certain embodiments, the inside of the first wall W1, the second wall W2, and the one or more side walls SW1, SW2, SW3, SW4 define the reaction volume 115 of the reaction chamber 110. Substrates 120 are processed within the reaction volume 115.

The reaction chamber 110 may comprise a lid, door or a hatch for loading and unloading substrate(s) 120 to and from the reaction volume 115. For instance, in an apparatus 100 according to FIGS. 1a and 1b, the door may be positioned in the bottom wall of the reaction chamber 110. Alternatively, (un)loading of substrates through the side walls of the reaction chamber 110, or top loading may be possible in certain embodiments.

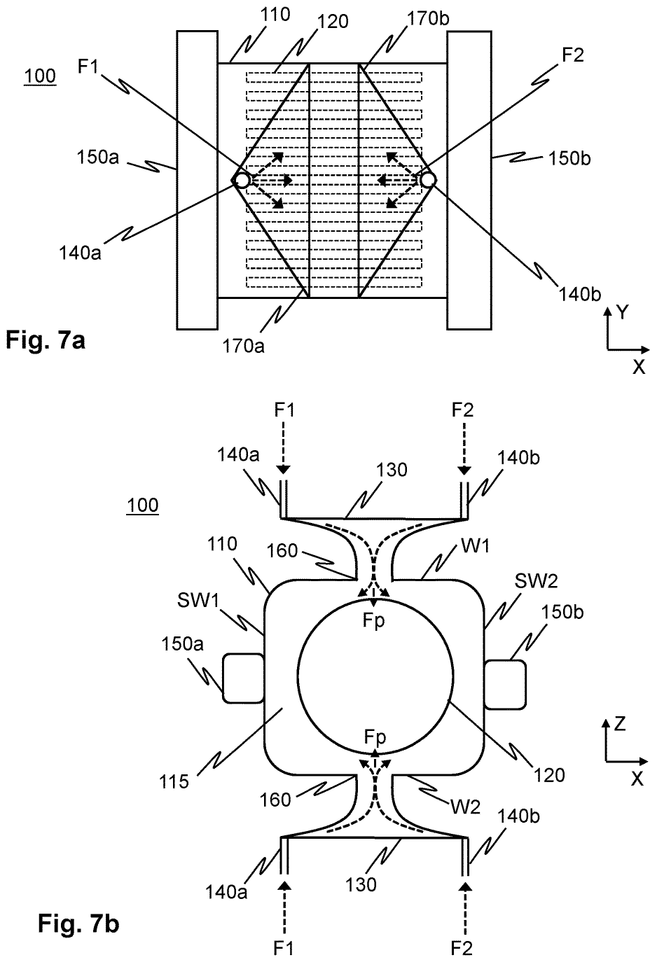

In certain embodiments, the apparatus 100 is configured to process one or more substrates 120. In certain embodiments, one or more substrates 120 or stacks of substrates 120 can be processed within the reaction volume 115 of the reaction chamber 110 depending on the configuration of the apparatus 110, as discussed in more detail below. For example, FIG. 1a schematically shows a cross-sectional side view substrate processing apparatus 100 for processing a single substrate 120 according to certain embodiments. FIG. 1b shows a cross-sectional top view of a corresponding apparatus 100. Correspondingly, FIGS. 6a and 6b schematically show a cross-sectional views of a substrate processing apparatus 100 for processing two stacks of substrates 120 according to certain embodiments.

In certain embodiments, the apparatus 100 comprises one or more substrate holders 125 to accommodate the one or more substrates 120 within the reaction chamber 110. In certain embodiments, the substrate holder(s) 125 is (are) rotatable.

In certain embodiments, the first wall W1, second wall W2 and one or more side walls SW1, SW2, SW3, SW4 are planar. In certain embodiments, at least one of the first wall W1, second wall W2 and one or more side walls SW1, SW2, SW3, SW4 is planar. In certain embodiments, the first wall W1, second wall W2 and/or one or more side walls SW1, SW2, SW3, SW4 comprise at least one curved wall. In certain embodiments, the first wall W1, second wall W2 and/or one or more side walls SW1, SW2, SW3, SW4 are curved walls.

In certain embodiments, the first wall W1, second wall W2 and one or more side walls are sections of reaction chamber walls. In certain embodiments, the first wall W1, second wall W2 and one or more side walls are planar sections of reaction chamber walls. In certain embodiments, the first wall W1, second wall W2 and one or more side walls SW1, SW2, SW3, SW4 are parts or sections of one or more curved reaction chamber walls. In certain embodiments, the first wall W1 and second wall W2 are sections of the reaction chamber walls to which an injection manifold 130 can be arranged. In certain embodiments, the each of the one or more side walls SW1, SW2, SW3, SW4 comprise one or more sections to which exhaust port or ports 150a, 150b can be arranged.

In certain embodiments, the one or more side walls SW1, SW2, SW3, SW4 extend between (edges of) the first wall W1 and (edges of) the second wall W1. In certain embodiments, the apparatus 100 comprises four side walls SW1, SW2, SW3, SW4. In certain embodiments, the side walls SW1, SW2, SW3, SW4 are aligned perpendicular to the first wall W1. In certain embodiments, the side walls SW1, SW2, SW3, SW4 are aligned perpendicular to the second wall W2. In certain embodiments, the side walls SW1, SW2, SW3, SW4 together with the first wall W1 and the second wall W2 are configured to define a cuboid-like or rectangular reaction chamber 110. In certain embodiments, the side walls SW1, SW2, SW3, SW4 together with the first wall W1 and the second wall W2 are configured to define at least a partially rounded reaction chamber 110. The processing volume 115, wherein substrate(s) is (are) accommodated for processing, is defined by the interior of the reaction chamber 110. Advantageously, reaction chambers of various shapes may be used.

In certain embodiments, the apparatus 100 comprises a cylindrical or curved wall comprising a plurality of wall sections. In certain embodiments, the curved reaction chamber wall comprises the first wall section W1 and second wall section W2 opposite to each other and a curved side wall section connecting the first wall section W1 and the second wall section W2. In certain embodiments, the curved side wall section comprises at least first side wall (section) SW1 and second side wall (section) SW2. In certain embodiments, the second side wall (section) SW2 is located opposite to the first side wall (section) SW1. In certain embodiments, the second side wall (section) SW2 is parallel to the fist side wall (section) SW1.

In certain embodiments, the apparatus 100 comprises one injection manifold 130, first injection manifold, to feed precursor flow Fp to the reaction chamber 110. Non-limiting examples of such apparatuses 100 are shown in FIGS. 1a-6b and 9a-13b. In certain embodiments, the first injection manifold 130 is attached to the first wall W1. That is, in certain embodiments, the first wall W1 is the wall of the reaction chamber 110 to which the first injection manifold 130 is attached.

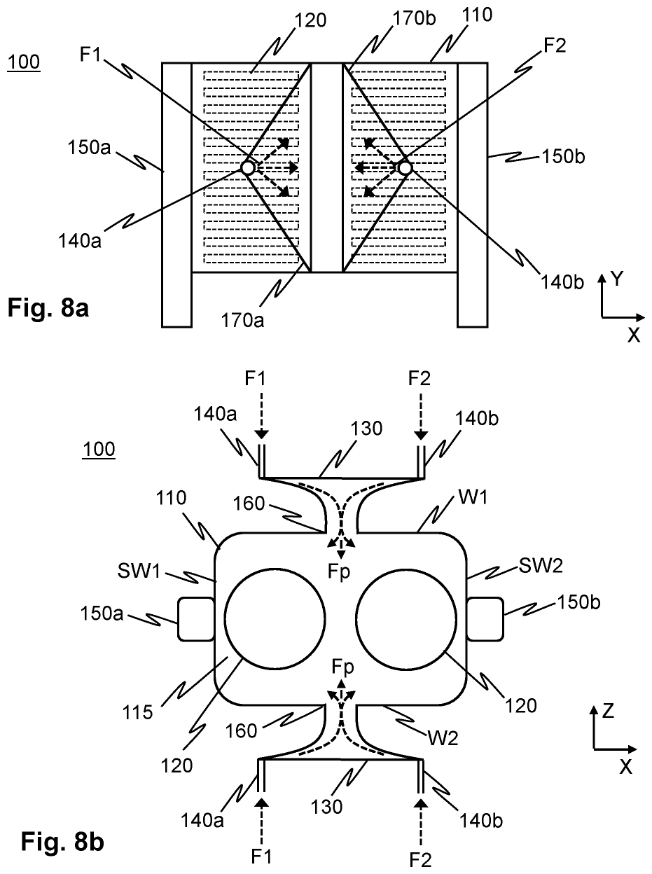

In certain embodiments, the apparatus 100 comprises at least one injection manifold 130. In certain embodiments, the apparatus 100 comprises two injection manifolds 130, a first injection manifold and a second injection manifold. In certain embodiments, the first injection manifold is attached to the first wall W1 and the second injection manifold is attached to the second wall W2 of the reaction chamber 110 which is located opposite to the first wall W1 (on opposite side of the reaction chamber 110). That is, in certain embodiments, the second wall W2 is the wall of the reaction chamber 110 to which the second injection manifold 130 is attached. Non-limiting examples of such apparatuses are shown in FIGS. 7a-8b.

In certain embodiments, the apparatus 100 comprises two exhaust ports, first exhaust port 150a and second exhaust port 150b. The two exhaust ports 150a, 150b are openings in reaction chamber (side) walls through which the apparatus is configured to remove fluid from (the reaction volume 115 define by) the reaction chamber 110. That is, the two exhaust ports 150a, 150b enable removal of fluid flow from the reaction volume 115 within the reaction chamber 110 to outside of the reaction chamber 110. In certain embodiments, the two exhaust ports 150a, 150b are connected to one or more vacuum pump through pump lines 152a, 152b. Exemplary positioning of pump lines 152a, 152b with respect to the exhaust ports 150a, 150b is shown in FIGS. 1a-1b, however, the person skilled in the art understands that other arrangements are possible too.

When referring to the shape of the two exhaust ports 150a, 150b, the shape refers to the shape of the exhaust port opening on or along the plane of inner surface of one or more reaction chamber side walls SW1, SW2, SW3, SW4. In certain embodiments, the two exhaust ports 150a, 150 are elongated openings extending at least partially across the one or more side walls SW1, SW2, SW3, SW4. In certain embodiments, the two exhaust ports 150a, 150 are rectangular. In certain embodiments, the two exhaust ports 150a, 150 are oblong. In certain embodiments, the two exhaust ports 150a, 150 are oval. In certain embodiments, the two exhaust ports 150a, 150 are polygonal.

In certain embodiments, the two exhaust ports 150a, 150b are arranged parallel to each other. In certain embodiments, the two exhaust ports 150a, 150b are arranged to at least one (section) of the one or more side walls (wherein the side walls are different from the first wall W1 and second wall W2).

In certain embodiments, the two exhaust ports 150a, 150b are arranged to reaction chamber side walls SW1, SW2, SW3, SW4 adjacent to the first wall W1. In certain embodiments, the two exhaust ports 150a, 150b are arranged to the one or more side walls SW1, SW2, SW3, SW4 adjacent to the first wall W1. In certain embodiments, the two exhaust ports 150a, are arranged to at least one of the one or more side walls SW1, SW2, SW3, SW4 immediately adjacent to the first wall W1. In certain embodiments, the two exhaust ports 150a, 150b are arranged immediately adjacent to the first wall W1.

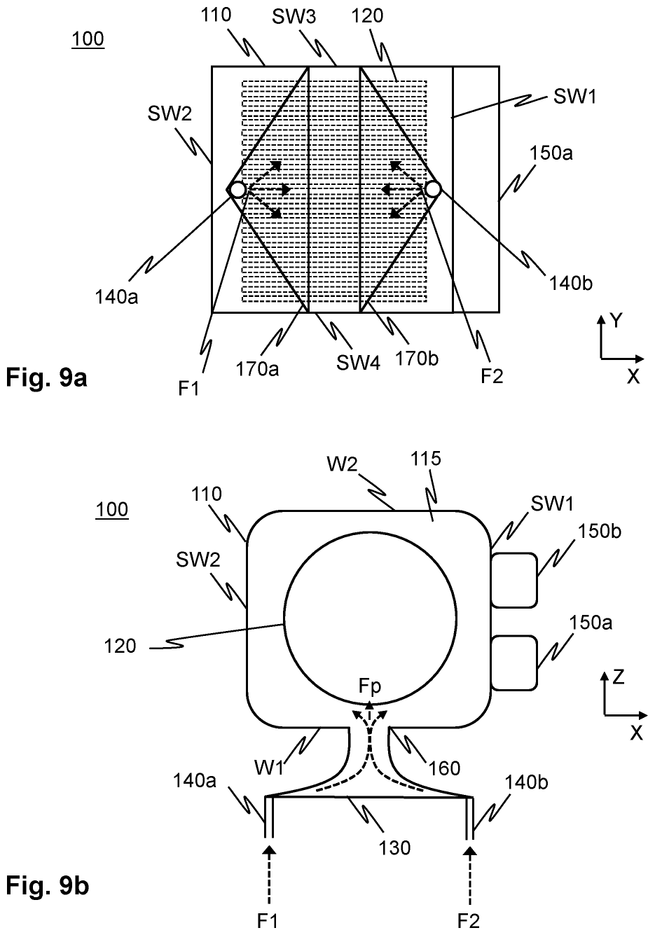

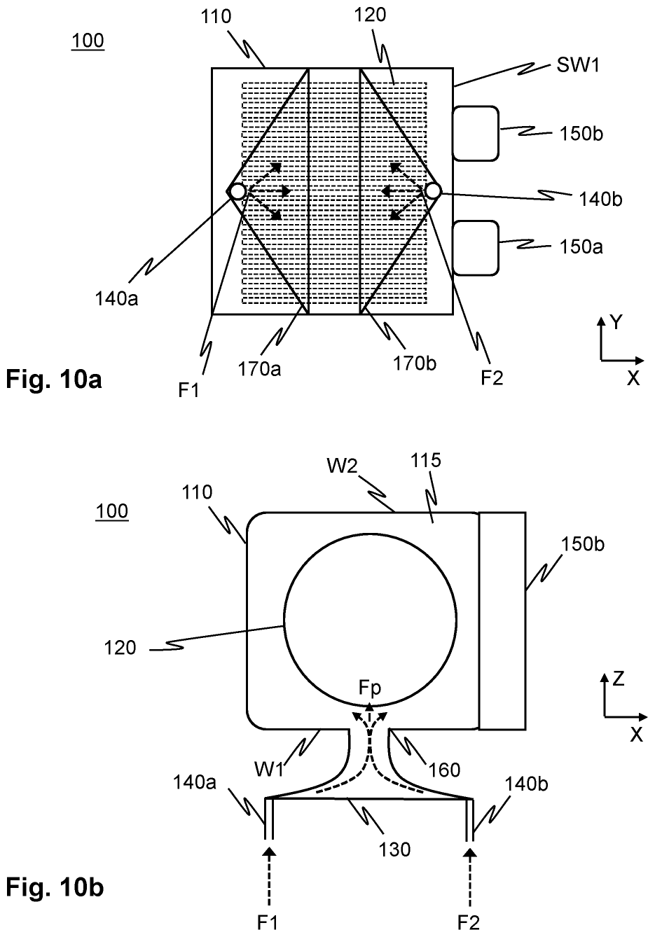

In certain embodiments, the two exhaust ports 150a, 150b are arranged adjacent to each other at the same side wall (for example, at the first side wall SW1). Non-limiting examples of such apparatuses are shown in FIGS. 9a-10b.

In certain embodiments, the two exhaust ports 150a, 150b are arranged to different side walls, first side wall SW1 and second side wall SW2. In certain embodiments, the first side wall SW1 is located opposite to the second side wall SW2 (at opposite side of the reaction chamber 110). Non-limiting examples of such apparatuses are shown in FIGS. 1a-8b, 13a and 13b. In certain embodiments, the two exhaust ports 150a, 150b are located at opposite sides of the reaction chamber 110. In certain embodiments, the two opposite exhaust ports 150a, 150b are located at opposite sides of one or more substrates 120 accommodated within the reaction chamber 110.

In certain embodiments, the two opposite exhaust ports 150a, 150b are symmetrically arranged. In certain embodiments, the two opposite exhaust ports 150a, 150b are symmetrically arranged with respect to the (first) injection manifold 130. In certain embodiments, the two opposite exhaust ports 150a, 150b are symmetrically arranged with respect to the reaction chamber 110. In certain embodiments, the two opposite exhaust ports 150a, 150b are symmetrically arranged with respect to one or more substrates 120 arranged within the reaction chamber 110.

In certain embodiments, the exhaust ports 150a, 150b are connected to a vacuum source or vacuum sources, such as a vacuum pump or pumps (through respective pump lines 152a, 152b).

In certain embodiments, the two exhaust ports 150a, 150b are arranged to one side wall (first side wall SW1, or a section of the (first) side wall SW1) or opposite (sections of) side walls (first and second side walls SW1, SW2) which is/are parallel to the direction in which the entrance opening 160 extends across the first wall W1. In certain embodiments, the two exhaust ports 150a, 150b are arranged to a side wall or opposite side walls which is/are perpendicular to the direction in which the entrance opening 160 extends across the first wall W1.

In certain embodiments, the two exhaust ports 150a, 150b are arranged to a side wall or opposite side walls SW1, SW2, SW3, SW4 which is/are parallel to a height direction of a substrate stack accommodated within the reaction chamber 110. In certain embodiments, the two exhaust ports 150a, 150b are arranged to a side wall or opposite side walls SW1, SW2, SW3, SW4 which is/are perpendicular to a height direction of a substrate stack accommodated within the reaction chamber 110.

In certain embodiments, the two exhaust ports 150a, 150b are configured to extend at least partially across a dimension of the side wall or walls SW1, SW2 at which the exhaust ports 150a, 150b are located. In certain embodiments, the two exhaust ports 150a, 150b are configured to extend (fully) across, in one dimension, the (entire) respective side wall or walls SW1, SW2 at which the exhaust ports 150a, 150b are located. Advantageously, fluid may be more efficiently removed from the reaction volume 115.

In certain embodiments, the two exhaust ports 150a, 150b are configured extend (as exhaust channels) beyond the respective side wall or walls SW1, SW2 at which they are located. Such exemplary apparatuses according to certain embodiments are shown in FIGS. 6a-8b. Advantageously, flow pattern out of the reaction volume may be controlled by the exhaust ports and/or positioning of exhaust lines to the exhaust ports.

In certain embodiments, the two exhaust ports 150a, 150b extend at least partially across the respective side wall or walls SW1, SW2 in a direction which is parallel to a plane defined by the entrance opening 160 (and/or first wall W1). For instance, if the plane defined by the entrance opening 160 is horizontal, the two exhaust ports 150a, 150b may also be horizontally elongated openings at the one or more side walls SW1, SW2, SW3, SW4 in which they reside. Advantageously, uniform flow front through the processing volume may be established.

In certain embodiments, the two exhaust ports 150a, 150b extend at least partially across the respective side wall or walls SW1, SW2 in a direction which is perpendicular to a plane defined by the entrance opening 160 (and/or first wall W1). For instance, if the plane defined by the entrance opening 160 is horizontal, the two exhaust ports 150a, 150b may be extended (elongated) in vertical direction. Advantageously, flow direction within the processing volume may be guided by the positioning of the exhaust ports.

Advantageously, the two exhaust ports enable efficient purging and uniform fluid removal and thus improved processing efficiency across a dimension of a reaction chamber.

Furthermore, by having two exhaust ports 150a, 150b, fluid flow control within the reaction chamber may be further improved.

In certain embodiments, the two exhaust ports 150a, 150b are arranged opposite to each other in opposite side walls SW1, SW2, SW3, SW3 of the reaction chamber 110 and located in opposite sides of substrate(s). In certain embodiments, the two exhaust ports 150a, 150b are arranged adjacent to each other in one of the side walls (first side wall SW1). Advantageously, problems of cross flow reactors, such as uneven film thickness due to unidirectional flow, may be avoided or at least reduced due to positioning of the exhaust ports. Furthermore, the two exhaust ports enable enhanced purging and thus improved reaction efficiency.

In certain embodiments, the two exhaust ports 150a, 150b comprise a perforated structure, such as a perforated reaction chamber side wall. Advantageously, the perforated structure may enable improved flow and pressure control within the reaction chamber 110.

The two exhaust ports 150a, 150b and the at least one injection manifold 130 are located at different walls of the reaction chamber 110. In certain embodiments, the first wall W1 and second wall W2 (to which injection manifold(s) may be attached) are different from side walls (to which exhaust ports 150a, 150b may be arranged) of the reaction chamber 110. In other words, both an injection manifold 130 and an exhaust port 150 (or two exhaust ports 150) may not be located at the same reaction chamber wall (i.e. enabling fluid inflow and outflow through the same reaction chamber wall) or arranged opposite to each other (i.e. enabling direct cross-flow through the reaction chamber 110).

In certain alternative embodiments, the two exhaust ports 150a, 150b are arranged to the second wall W2 opposite to the first wall W1. FIGS. 11a-12b show exemplary non-limiting examples of such apparatuses 100. In certain embodiments, the two exhaust ports 150a, 150b extend at least partially across the second wall W2 parallel to each other. In certain embodiments, the two exhaust ports 150a, 150b extend across the second wall W2 parallel to a direction in which the entrance opening 160 extends across the first wall W1. In certain embodiments, the two exhaust ports 150a, 150b extend across the second wall W2 perpendicular to the direction in which the entrance opening 160 extends across the first wall W1. Advantageously, in such embodiments reactant flow through the processing volume and removal from the processing volume may be enhanced.

In certain embodiments, the apparatus 100 comprises at least one injection manifold 130 to feed precursor (fluid) flow Fp to the reaction volume 115 of the reaction chamber 110. In certain embodiments, the injection manifold 130 is further configured to feed (inert) carrier gas(es) and/or purging gas(es) to the reaction chamber 110. The injection manifold 130 in FIG. 1a is highlighted within a dashed rectangle with rounded corners. The injection manifold 130 feeds the precursor flow FP to the reaction chamber 110 through the entrance opening 160. The apparatus comprises the entrance opening 160 at the first wall W1. That is, the entrance opening 160 provides a fluid communication path from the injection manifold 130 through the first wall W1 to the reaction volume 115.

In certain embodiments, the precursor flow Fp comprises reaction precursors. In certain embodiments, the precursor flow Fp comprises inert carrier gas. In certain embodiments, the precursor flow Fp comprises a mixture of reaction precursors and inert carrier gas. In certain embodiments, the precursor flow Fp comprises only inert carrier gas.

The (at least one) injection manifold 130 enables improved fluid delivery to the one or more substrates 120 accommodated within (the reaction volume 115 of) the reaction chamber 110 for substrate processing. Advantageously, precursor flow Fp may be more evenly distributed and more uniformly delivered to the substrate surfaces, also during batch processing.

In certain embodiments, at least one injection manifold 130 is attached to the reaction chamber 110 wall, the first wall W1. In certain embodiments, the at least one injection manifold 130 has a funnel-shaped cross-section which gradually narrows towards a reaction chamber entrance opening 160 and the reaction chamber 110. The precursor flow Fp propagates from the injection manifold 130 through an entrance opening 160 (or entrance openings 160 in certain embodiments) to the reaction chamber 110 and further across the reaction volume 115 to the two exhaust ports 150a, 150b.

The entrance opening 160 is an opening through the first wall W1 that enables fluid flow through the first wall W1 from (the injection manifold 130) outside (the reaction volume 115 of) the reaction chamber 120 to the reaction volume 115 within the reaction chamber 110. In certain embodiments, the entrance opening 160 is rectangular. In certain embodiments, the entrance opening 160 is an elongated opening. In certain embodiments, the entrance opening 160 is oval. In certain embodiments, the entrance opening 160 is polygonal.

In certain embodiments, the apparatus 100 comprises one injection manifold 130, first injection manifold. In certain embodiments, the first injection manifold is attached to (outer surface of) the first wall W1 of the reaction chamber 110. For example, in FIGS. 1a, 2a and 3a the first wall W1 is the top wall of the apparatus, and in FIGS. 1b, 2b and 3b the first wall W1 is directed towards the viewer. That is, the first wall W1 is the wall of the reaction chamber 110 to which the injection manifold 130 is attached to. The first wall W1 may be a top wall, bottom wall, or a lateral wall of the reaction chamber 110. That is, it is up to the skilled person to select the most suitable position and orientation for the apparatus 100 and injection manifold 130 depending on the situation, for example, based on available space and reaction chamber geometry.

In certain embodiments, the apparatus 100 comprises two injection manifolds 130, first injection manifold and second injection manifold. Non-limiting examples of apparatuses 100 according to certain embodiments comprising two injection manifolds are schematically shown in FIGS. 7a-8b. In certain embodiments, the two injection manifolds 130 are positioned opposite to each other. In certain embodiments, the two injection manifolds 130 are located at opposite sides (walls) of the reaction chamber 110. In certain embodiments, the two injection manifolds 130 are positioned in opposite sides of the one or more substrates 120 accommodated within the reaction chamber 110. In certain embodiments, the two injection manifolds 130 are attached to opposite walls of the reaction chamber 110, that is, to a first wall W1 and a second wall W2 which is opposite to the first wall W1.

In certain embodiments, the two injection manifolds 130 are configured to feed respective precursor flows Fp into the reaction chamber 110 through respective entrance openings 160 located at the first wall W1 and second wall W2. In certain embodiments, the two injection manifolds 130 are configured to feed respective precursor flows Fp into the reaction chamber 110 through entrance openings 160 located at opposite sides of the reaction chamber 110 facing each other.

The at least one injection manifold 130 is in fluid communication with (the reaction volume 115 of) the reaction chamber 110 through the entrance opening 160. The at least one injection manifold 130 is configured to feed fluid flow, such as precursor flow Fp, to the reaction chamber 110 through an entrance opening 160 located at the first wall W1 (and, in certain embodiments, second wall W2) of the reaction chamber 110. The entrance opening 160 is encircled with a dashed rectangle with rounded corners in FIG. 1b. In case of the apparatus 100 comprising two injection manifolds 130, each of the two injection manifolds 130 is configured to feed respective precursor flow Fp and/or flow of (inert) carrier gas or purging gas to the reaction volume 115 through a respective entrance opening 160, as shown for example in FIG. 7b.

In certain embodiments, the injection manifold 130 comprises a first inlet 140a and a second inlet 140b. In certain embodiments, the injection manifold 130 is configured to receive first fluid flow F1 from the first inlet 140a and second fluid flow F2 from the second inlet 140b. In certain embodiments, the at least one injection manifold 130 is configured to direct the first fluid flow F1 and the second fluid flow F2 received from the respective gas inlets 140a, 140b towards the entrance opening 160. In certain embodiments, the first fluid flow F1 and the second fluid flow F2 approach the entrance opening 160 from opposite directions. That is, in certain embodiments the general propagation direction of the first fluid flow F1 and the second fluid flow F2 within the injection manifold 130 from the respective gas inlets 140a, 140b towards the entrance opening 160 is towards each other. The first fluid flow F1 and the second fluid flow may, for example, comprise precursor chemical(s), carrier gas(es) and/or purge gas(es).

In certain embodiments, the at least one injection manifold 130 is configured to combine the first fluid flow F1 and the second fluid flow F2 into the precursor flow Fp within the injection manifold 130. The injection manifold 130 is configured to combine the first and second fluid flows F1, F2 into the precursor flow Fp within a transition region located upstream of the entrance opening 160 and between opposite expansion volumes 170a, 170b. The injection manifold 130 is configured to feed the precursor flow Fp to (the reaction volume 115 of) the reaction chamber 110 through the entrance opening 160. Advantageously, mixing and uniformity of the precursor flow may be improved.

In certain embodiments, the injection manifold 130 is configured to spread the first fluid flow F1 and the second fluid flow F2 to a dimension of the entrance opening 160 extending across the first wall W1 of the reaction chamber 110 within the injection manifold before combining said flows F1, F2 to form the precursor flow Fp. Consequently, the precursor flow may enter the reaction chamber 110 as a uniform flow front extending, for example, across the entire width of the reaction chamber 110. Advantageously, more homogeneous flow conditions within the reaction volume may be achieved.

In certain embodiments, the injection manifold 130 is configured to develop an essentially laminar precursor flow Fp within the injection manifold 130 to be fed into the reaction volume 115. In certain embodiments, the injection manifold 130 is configured to feed the precursor flow Fp to the reaction chamber 110 as essentially laminar flow. In certain embodiments, the precursor flow Fp propagates through the reaction chamber 110 (from the entrance opening(s) 160 to the two exhaust ports 150a, 150b) as essentially laminar flow. Advantageously, the uniformity and distribution of the combined precursor flow Fp within the reaction chamber 110 may be further improved by the injection manifold.

In certain embodiments, the injection manifold 130 is configured to direct the first fluid flow F1 and the second fluid flow F2, within the injection manifold 130, to propagate substantially towards each other. In certain embodiments, the general propagation directions of the first and second fluid flows F1, F2 within the injection manifold 130 towards the entrance opening 160 are parallel to a plane defined by the entrance opening 160 (that is, parallel to the first wall W1 of the reaction chamber 110 in certain embodiments and, for example, along X direction in FIG. 1a).

In certain embodiments, the injection manifold 130 is configured to spread the first and second fluid flows F1, F2 both laterally (e.g. in Z direction in FIGS. 1a and 1b) parallel to the first wall W1 and vertically (e.g. in Y direction in FIGS. 1a and 1b) towards the first wall W1 while the flows F1, F2 propagate towards the entrance opening 160.

In certain embodiments, the injection manifold 130 is configured to laterally spread said fluid flows F1, F2, in direction parallel to the plane defined by the first wall W1 and the entrance opening 160 (i.e. Z direction in FIG. 1b for example), before combining said fluid flows F1, F2 into the precursor flow Fp.

In certain embodiments, the injection manifold 130 is further configured to gradually spread the first fluid flow F1 and the second fluid flow F2 (vertically) towards the reaction chamber (perpendicular to the direction of general propagation direction and lateral spreading, e.g. in Y direction in FIG. 1a), while said fluid flows propagate towards each other (in X direction in FIG. 1a) and the entrance opening 160. In certain embodiments, said vertical spreading is in a direction perpendicular to the plane defined by the reaction chamber opening 160 (and first wall W1 of the reaction chamber 110). Advantageously, the laterally expanding flows from the first and second gas inlet 14a, 140b may be gradually spread and directed (vertically) towards the reaction chamber 110. Advantageously, mixing and control of distribution of the first fluid flow F1 and the second fluid flow F2 may be improved. Further, formation and support of laminar precursor flow Fp may be improved.

In certain embodiments, the injection manifold 130 is configured to turn the first fluid flow F1 and the second fluid flow F2, propagating through the injection manifold 130, substantially 90 degrees towards the reaction chamber 110 within the injection manifold 130 before feeding said fluid flows F1, F2 as the precursor flow Fp to the reaction chamber 110. In certain embodiments, the injection manifold 130 is configured to turn the first fluid flow F1 and the second fluid flow F2 upon collision of said flows F1, F2 within the transition region of the injection manifold 130. The changes in flow direction advantageously enable more homogeneous fluid distribution and mixing.

In certain embodiments, the injection manifold 130 comprises a first expansion volume 170a configured to spread the first fluid flow F1 laterally (in a plane defined by the first wall W1) and vertically (towards the reaction chamber 110). Likewise, in certain embodiments, the injection manifold 130 comprises a second expansion volume 170b configured to laterally and vertically spread the second fluid flow F2. In certain embodiments, the expansion volumes 170a, 170b are configured to deliver the fluid flows F1, F2 from the first and second gas inlet 140a, 140b, respectively, towards the transition region and entrance opening 160.

In certain embodiments, the first expansion volume 170a and the second expansion volume 170b are opposite and mutually mirror symmetric sub-volumes within the injection manifold 130 (whose dimensions are defined by the inner walls of the injection manifold 130). Due to the first expansion volume 170a and the second expansion volume 170b being opposite to each other, the first fluid flow F1 and second fluid flow F2 propagate essentially towards each other within the respective first and second expansion regions 170a, 170b.

In certain embodiments, the injection manifold 130 comprises a transition region between the two expansion volumes 170a, 170b (and upstream of the entrance opening 160). In certain embodiments, the injection manifold 130 is configured to combine the first fluid flow F1 and the second fluid flow F2, arriving from respective expansion volumes 170a, 170b, into the precursor flow Fp within the transition region. That is, the transition region is a volume within the injection manifold wherein the first and second fluid flows F1, F2 are mixed before feeding them through the entrance opening 160 as the precursor flow Fp. In certain embodiments, the transition region is located immediately upstream of the entrance opening 160 and between the two expansion volumes 170a, 170b.

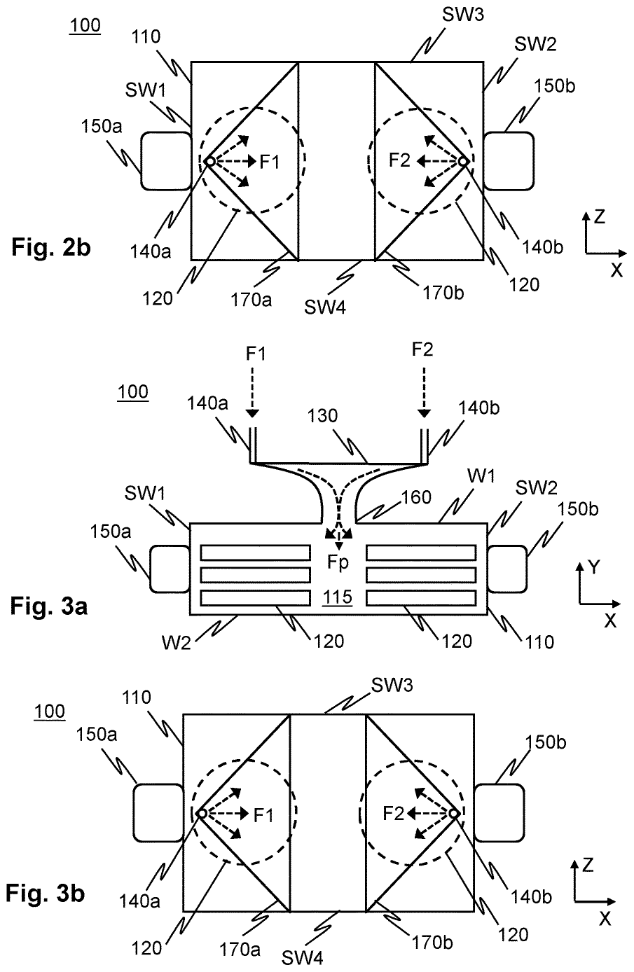

In certain embodiments, when the apparatus 100 according to certain embodiments is viewed through the injection manifold 100 towards the reaction chamber 110, as for instance in FIGS. 1b and 2b, the cross-section of the injection manifold 130 forms a hexagonal shape comprising two laterally outwards extending triangular first and second expansion volumes 170a, 170b, and the rectangular entrance opening 160 and transition region above the entrance opening 160 therein between.

In certain embodiments, the injection manifold 130 is configured to receive first fluid flow F1 from a first inlet 140a and second fluid flow F2 from a second inlet 140b to the first expansion volume 170a and to the second expansion volume 170b, respectively. In certain embodiments, the first inlet 140a and the second inlet 140b are configured to provide the first fluid flow F1 and the second fluid flow F2 into the respective expansion volumes 170a, 170b such that said fluid flows F1, F2 are forced to turn substantially 90 degrees towards each other upon entering the respective expansion volume 170a, 170b. The expansion volumes 170a, 170b are configured to guide the first and second fluid flows F1, F2, respectively from the first gas inlet 140a and the second gas inlet 140b towards the entrance opening 160 while simultaneously spreading said fluid flows F1, F2 at least laterally to the dimension of the entrance opening 160 extending across the first wall W1 (and the reaction chamber 110). In certain embodiments, the first expansion volume 170a and the second expansion volume 170b are further configured to gradually spread the respective fluid flows F1, F2 perpendicular to the lateral spreading and towards the entrance opening 160 and first wall W1 of the reaction chamber 110.

In certain embodiments, the first expansion volume 170a and the second expansion volume 170b comprise triangular cross-sections in a plane parallel to the first wall W1 of the reaction chamber 110, as shown, for instance in FIG. 1b. Advantageously, the triangular shape enables and guides the lateral spreading of fluid flows from a gas inlets 140a, 140b towards the transition region and entrance opening 160.

In certain embodiments, the triangular expansion volumes 170a, 170b are configured to extend from the respective gas inlets 140a, 140b to the transition region located immediately upstream of the entrance opening 160, such that the respective gas inlets 140a, 140b are located at a corner of each respective triangle which is farthest away from the entrance opening 160. In certain embodiments, the sides of the entrance opening 160 extending across the dimension of the reaction chamber 110 define the sides of the triangles opposite to said corners with the respective gas inlet 140a, 140b. That is, in certain embodiments, both triangular cross-sectional shapes of the expansion volumes 170a, 170b are configured to widen towards the entrance opening 160 and towards each other.

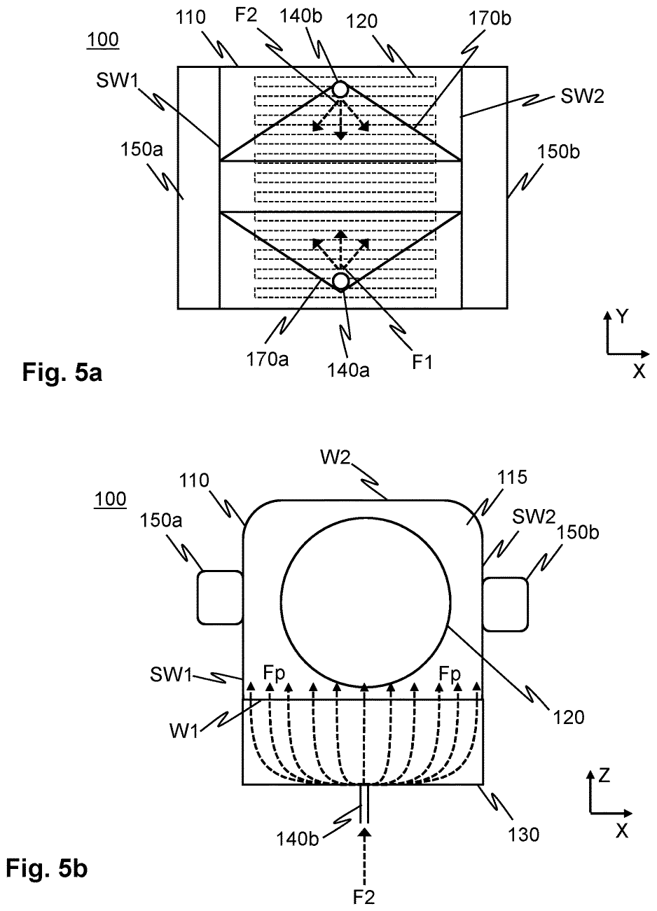

In certain embodiments, the at least one injection manifold 130 is centrally positioned with respect to the first wall W1 of the reaction chamber 110. In certain embodiments, the entrance opening 160 is rectangular. In certain embodiments, the entrance opening 160 is reaction chamber wide, as shown, for example in FIGS. 1b, 2b and 3b. In certain embodiments, the entrance opening 160 is reaction chamber high, as shown, for example in FIGS. 4a, 5a, 6a and 7a. That is, in certain embodiments the entrance opening 160 extends across the entire (first, or fist and second) wall of the reaction chamber 110.

In certain embodiments, the entrance opening 160 extends centrally across the (entire) first wall W1 (and, in certain embodiments, another entrance opening similarly across second wall W2) of the reaction chamber 110 in a direction which is perpendicular to the first side wall SW1 to which the first exhaust port 150a is arranged. In certain embodiments, the entrance opening 160 extends centrally across the (entire) first wall W1 (and, in certain embodiments, second wall W2) of the reaction chamber 110 in a direction which is parallel to the first side wall SW1 to which a first exhaust port 150a is arranged.

Consequently, precursor flow Fp, distributed to a dimension of the reaction chamber 110 (in a dimension in which the entrance opening extends across the first wall W1) within the fluid distributor 130 is configured to propagate across the reaction volume 115 from the entrance opening 160 towards the first and second exhaust ports 150a, 150b arranged adjacently to the first side wall SW1 or opposite to each other at the first side wall SW1 and second side wall SW2, respectively. Advantageously, the injection manifold 130 and entrance opening 160 enable a uniformly distributed precursor fluid flow Fp to be delivered to the reaction chamber 110 across the entire dimension (width, height, or length depending on the orientation and dimensions of the apparatus 100) of the reaction chamber 110.

In certain embodiments, the apparatus 100 is configured to propagate the precursor flow Fp through the reaction chamber 110 as essentially laminar flow. Consequently, deposition uniformity and substrate saturation may be further improved.

In certain embodiments, the reaction chamber 110 is configured to accommodate one or more substrates 120 within the reaction volume 115 for substrate processing. The substrates 120 may be processed as single substrate(s) or as stack(s) or batch(es). The substrate(s) 120 may be, for example, circular silicon wafer(s). The skilled person appreciates that other shapes and/or materials are possible too.

In certain embodiments, the reaction chamber 110 is configured to accommodate one or more individual substrates 120 within the reaction volume 115. In certain embodiments, the reaction chamber 110 is configured to accommodate one or more stacks substrates 120 within the reaction volume 115.

In certain embodiments, the one or more substrates 120 or substrate stacks are positioned centrally within the reaction chamber 110 with respect to the injection manifold 130 (and entrance opening 160). In certain embodiments, the substrate 120 or substrates 120 are positioned symmetrically within the reaction chamber 110 with respect to the injection manifold 130 (and entrance opening 160).

In certain embodiments, as schematically shown in FIGS. 1a and 1b, the reaction chamber 110 is configured to accommodate a single substrate 120. Thus, in certain embodiments, the apparatus 100 is configured to process a single substrate 120. In certain embodiments, the single substrate 120 is positioned centrally with respect to the apparatus 100 such that entrance opening 160 is located along central axis of the substrate 120. In certain embodiments, (the central axis of) the planar surface of the single substrate 120 is aligned towards the injection manifold 130.

In certain other embodiments, as schematically shown in the non-limiting examples of FIGS. 2a and 2b, the apparatus 100 is configured to accommodate at least two individual substrates 120 at the same time positioned laterally next to each other (within the same plane). In certain embodiments, the apparatus 100 is configured to accommodate two or more adjacently positioned substrates 120 simultaneously, such as 2, 4, or 6 substrates 120. In certain embodiments, central axes of the substrates 120 perpendicular to the planar surfaces of the two or more substrates 120 are aligned perpendicular to the first wall W1 or a plane defined by the entrance opening 160.

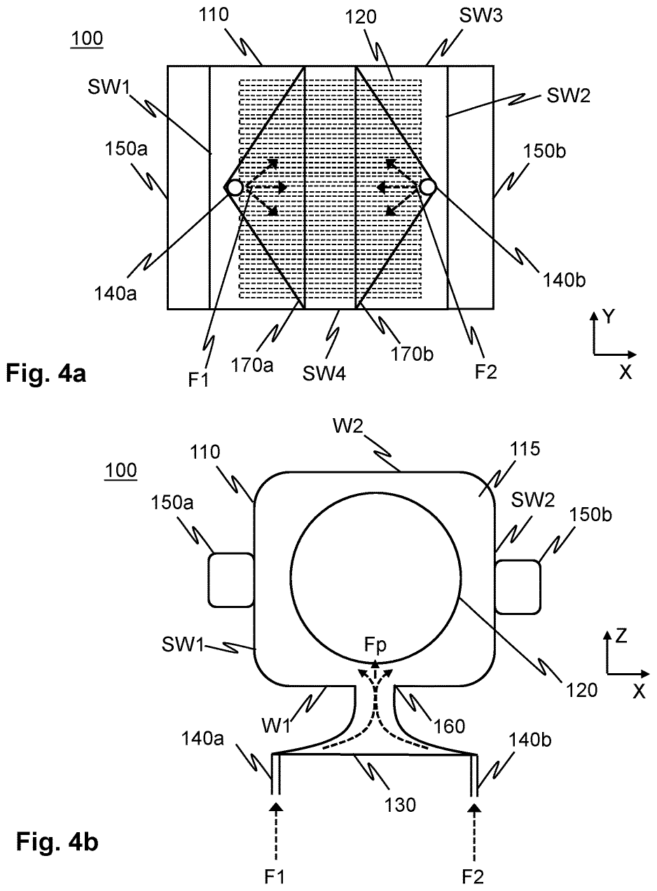

In certain embodiments, the reaction chamber 110 is configured to accommodate one or more stacks (or batches) of substrates 120, as schematically shown, for example in FIGS. 3a-13b. In certain embodiments, the reaction chamber 110 is configured to accommodate 1, 2, 3 or 4 stacks of substrates 120. In certain embodiments, the one or more stacks (or batches) of substrates 120 are positioned centrally and symmetrically within the reaction chamber 110 with respect to the injection manifold 130. In certain embodiments, the one or more stacks (or batches) of substrates 120 are positioned centrally and symmetrically within the reaction chamber 110 with respect to the apparatus 100. In certain embodiments, the one or more stacks (or batches) of substrates 120 are positioned centrally and symmetrically within the reaction chamber 110 with respect to the reaction chamber 110. Advantageously, high throughput processing may be enabled by processing a stack or a plurality of stacks simultaneously. Further, the flow conditions through the stack or stacks of different sizes may be optimized by the alignment of the stack or stacks with respect to the entrance opening and exhaust ports.

In the substrate stack(s), the substrates 120 are aligned and positioned with their planar surfaces facing towards each other. In certain embodiments, the reaction chamber 110 is configured to accommodate a vertical stack or stacks of horizontally aligned substrates 120. In certain embodiments, the reaction chamber is configured to accommodate a horizontal stack or stacks of vertically aligned substrates 120. The substrates 120 in the stack(s) are spaced apart to allow fluid flow through the stack(s) and between the substrate surfaces.

In certain embodiments, the substrate stack or stacks comprise 2-50 substrates 120. In certain embodiments, the substrate stack or stacks comprise at least 10 substrates 120. In certain embodiments, the substrate stack or stacks comprise 15-30 substrates 120. In certain embodiments, the substrate stack or stacks comprise up to 35 substrates 120. In certain embodiments, the substrate stack or stacks comprise 25-50 substrates 120.

In certain embodiments, the height direction of the stack or stacks of substrates 120 within the reaction chamber 110 is aligned perpendicular to a plane defined by the first wall W1 and the entrance opening 160. A non-limiting example of such an alignment is shown for instance in FIG. 3a. In certain embodiments, the height direction of the stack or stacks of substrates 120 is aligned parallel to a to a plane defined by the first wall W1 and the entrance opening 160. Exemplary embodiment comprising such an alignment is shown for instance in FIG. 9a.

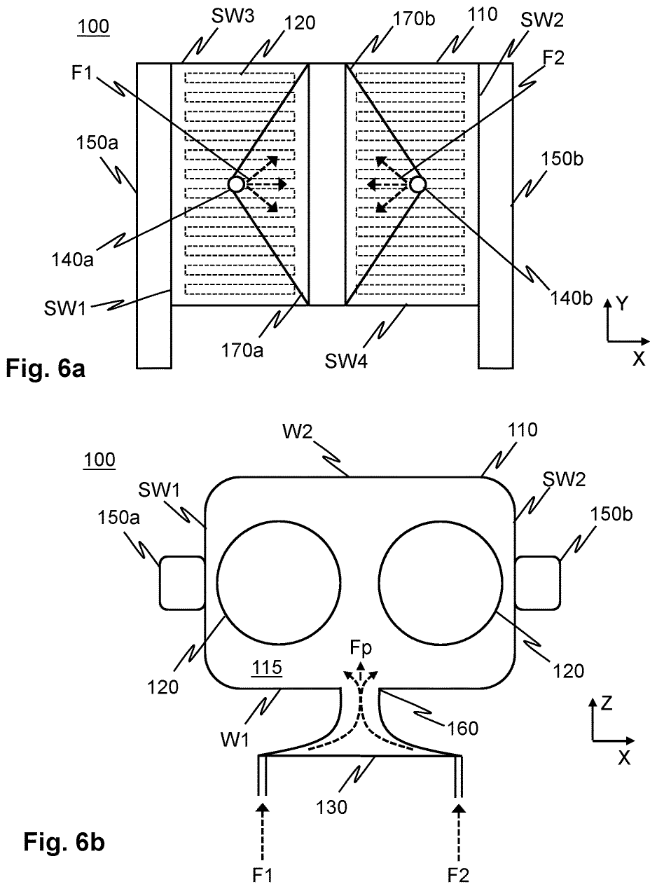

In certain embodiments, the height direction of the stack or stacks of substrates 120 within the reaction chamber 110 is aligned parallel to the direction in which entrance opening 160 extends across the width of the first wall W1, as shown for example in FIGS. 4a-4b and 6a-10b. In certain embodiments, the height direction of the stack or stacks of substrates 120 within the reaction chamber 110 is aligned perpendicular to the direction in which entrance opening 160 extends across the width of the first wall W1, as shown for example in FIGS. 3a-3b and 5a-5b.

In certain embodiments, the height direction of the stack or stacks of substrates 120 is aligned parallel to a plane defined by the side wall or (opposite) side walls SW1, SW2 comprising the two exhaust ports 150a, 150b, as shown for example in FIGS. 8a-8b.

In certain embodiments, the height direction of the substrate stack or stacks within the reaction chamber 110 is parallel to the direction at which exhaust ports 150a, 150b extend at least partly across respective side walls SW1, SW2 of the reaction chamber 110. See for example FIGS. 7a-8b. In certain embodiments, the height direction of the substrate stack or stacks within the reaction chamber 110 is perpendicular to the direction at which exhaust ports 150a, 150b extend at least partly across respective side walls SW1, SW2 of the reaction chamber 110. See for example FIGS. 10a-10b.

It is noted that within the scope of the present disclosure, various combinations regarding the mutual alignment of entrance opening, exhaust ports and substrates may be implemented as described herein. For instance, according to the non-limiting example embodiments depicted in FIGS. 3a and 3b, the apparatus 100 is configured to process two stacks of substrates 120 at the same time, wherein the height direction of the stacks is aligned perpendicular the first wall W1 of the reaction chamber 110 and parallel to the first and second side wall SW1, SW2. In another non-limiting example shown in FIGS. 7a and 7b, the apparatus is configured to process one stack of substrates 120, wherein the height direction of the stack is aligned parallel to planes defined by the first and second walls W1, W2, parallel to the direction in which the entrance openings 160 extend across said first and second walls W1, W2, and parallel to the first and second side walls W1, W2, and parallel to the direction in which the first and second exhaust ports 150a, 150b extend across the first and second side walls SW1, SW2, respectively.

In certain embodiments, the first gas inlet 140a, second gas inlet 140b, (center point of) injection manifold 130, (center point of) entrance opening 160, and the (center points of) two exhaust ports 150a, 150b are located in the same plane. In certain embodiments, the first gas inlet 140a, the second gas inlet 140b, and (center points of) the two opposite exhaust ports 150a, 150b are located in the same plane.

In certain embodiments, the apparatus 100 is mirror symmetric (with respect to a plane entering a reaction chamber 110 through an entrance opening 160). In certain embodiments, the apparatus 100 has at least one twofold axis of symmetry.

FIG. 14 shows a flow chart of a method according to certain embodiments. Optional steps are marked with dashed boxes. The illustrated process comprises various possible steps including some optional steps while also further steps can be included and/or some of the steps can be performed more than once. The process may be implemented, for example, in the thin-film deposition apparatus 100 described herein above. Structural features of the apparatus 100 have been discussed in the foregoing with respect to exemplary embodiments of FIGS. 1a-13b and thus will not be repeated in detail below.

Step 1410 comprises accommodating one or more substrates 120 within a reaction chamber 110. In certain embodiments, accommodating comprises accommodating one (individual) substrate 120.

In certain embodiments, according to an optional step 1415, accommodating comprises accommodating one or more (individual) substrates 120. In certain embodiments, the one or more substrates 120 are laterally separated from each other within the reaction chamber 110.

In certain embodiments, accommodating, according to an optional step 1420, comprises accommodating one or more stacks of substrates 120 within the reaction chamber 110. In certain embodiments, the stack or stacks are vertical stack(s) of horizontally aligned substrates 120. In certain embodiments, the stack or stacks are horizontal stack(s) of vertically aligned substrates 120. The surfaces of substrates 120 in the stack(s) are separated from each other such that fluid may flow through the stack to reach the substrate surfaces within the stack.

Optional step 1422 comprises aligning height direction of one or more stacks of substrates 120 in relation to exhaust port direction (extending across the first wall W1 of the reaction chamber 110). In certain embodiments, the method comprises aligning the height direction of the one or more stack of substrates 120 parallel to a direction in which the two exhaust ports 150a, 150b extend at least partially across the side wall or walls SW1, SW2, SW3, SW4 in which the two exhaust ports are arranged. In certain embodiments, the method comprises aligning the height direction of the one or more stack of substrates 120 perpendicular to a direction in which the two exhaust ports 150a, 150b extend at least partially across the side wall or walls SW1, SW2, SW3, SW4 in which the two exhaust ports are arranged.

Optional step 1424 comprises aligning height direction of one or more stacks of substrates in relation to entrance opening direction. In certain embodiments, the method comprises aligning the height direction of the one or more stack of substrates 120 parallel to a direction in which an entrance opening 160 of the reaction chamber 110 extends across the first wall W1. In certain embodiments, the method comprises comprising aligning the height direction of the one or more stack of substrates 120 perpendicular to a direction in which an entrance opening 160 of the reaction chamber 100 extends across the first wall W1.

Optional step 1425 comprises receiving first fluid flow F1 and second fluid flow F2 to the injection manifold 130 and combining the first fluid flow F1 and second fluid flow F2 within the injection manifold 130 to form the precursor flow Fp. In certain embodiments, the first and second fluid flows F1, F2 comprise reaction precursor or precursors, (inert) carrier gas(es) and/or purge gas.

Optional step 1430 comprises expanding the first fluid flow F1 and the second fluid flow F2 to a dimension of the reaction chamber 110 (in a direction in which the entrance opening 160 extends across the first wall W1) within the injection manifold 130 before combining said flows F1, F2 to form the precursor flow. In certain embodiments, expanding of the first fluid flow F1 and the second fluid flow F2 is performed within respective first expansion region 170a and second expansion region 170b of the injection manifold 130. In certain embodiments, expanding comprises propagating the first fluid flow F1 and the second fluid flow F2 essentially towards each other within the injection manifold 130 while expanding said flows F1, F2 laterally in directions parallel to a plane defined by the first wall W1. In certain embodiments, expanding comprises expanding the first fluid flow F1 and the second fluid flow F2 towards the reaction chamber 110 in a direction perpendicular to a plane defined by the first wall W1 while propagating the first fluid flow F1 and the second fluid flow F2 essentially towards each. In certain embodiments, the first expansion region 170a and second expansion region 170b are opposite to each other.

Step 1440 comprises feeding precursor flow Fp to the reaction chamber 110 for substrate processing by the injection manifold 130 through an entrance opening 160 in the first wall W1 of the reaction chamber 110.

In certain embodiments, according to an optional step 1445, feeding comprises feeding the precursor flow Fp to the reaction chamber by two injection manifolds 130.

In certain embodiments, according to optional step 1450, feeding comprises feeding the precursor flow Fp as (substantially) laminar flow to the reaction chamber 110.

Optional step 1455 comprises processing the one or more substrates 120 with alternating self-limiting surface reactions within the reaction chamber 110. In certain embodiments, self-limiting surface reactions follow the principles of ALD processing.

Step 1460 comprises removing fluid from the reaction chamber 110 through two exhaust ports 150a, 150b. In certain embodiments, the two exhaust ports 150a, 150b are parallel to each other. In certain embodiments, the two exhaust ports 150a, 150b are arranged adjacent to each other in one of the one or more side walls SW1, SW2, SW3, SW4, first side wall SW1. In certain embodiments, the two exhaust ports 150a, 150b are arranged opposite to each other in two opposite side walls, first side wall SW1 and second side wall SW2, of the reaction chamber 110. In certain embodiments, the two exhaust ports 150a, 150b are located in at least one of the one or more side walls SW1, SW2, SW3, SW4 immediately adjacent to the first wall W1. In certain embodiments, the side walls SW1, SW2, SW3, SW4 are different from the first wall W1 (and, in certain embodiments, second wall W2) of the reaction chamber 110 to which the injection manifold(s) 130 is (are) attached. In certain embodiments, the two opposite exhaust ports 150a, 150b are connected to a vacuum pump or vacuum pumps.

Without limiting the scope and/or interpretation of the claims, certain technical effects and/or advantages of one or more of the example embodiments disclosed herein are listed in the following. An advantage is that substrate processing quality, such as more uniform film thickness, may be improved, even when processing large batches or stacks of substrates. Another advantage is improved reaction efficiency. Yet another advantage is improved precursor distribution and utilization within the reaction chamber. Yet another advantage is improved purging efficiency and consequently also more efficient processing cycles. Yet another advantage is more efficient fluid removal from the processing volume and, consequently, more efficient processing. The one or more advantages may be realized due to improved distribution and more uniform provision of fluid(s) to the reaction chamber and improved flow control within the reaction chamber.

Various embodiments have been presented. It should be appreciated that in this document, words comprise, include, and contain are each used as open-ended expressions with no intended exclusivity.

The foregoing description has provided by way of non-limiting examples of particular implementations and embodiments a full and informative description of the best mode presently contemplated by the inventors for carrying out the invention. It is however clear to a person skilled in the art that the invention is not restricted to details of the embodiments presented in the foregoing, but that it can be implemented in other embodiments using equivalent means or in different combinations of embodiments without deviating from the characteristics of the invention.

Furthermore, some of the features of the afore-disclosed example embodiments may be used to advantage without the corresponding use of other features. As such, the foregoing description shall be considered as merely illustrative of the principles of the present invention, and not in limitation thereof. Hence, the scope of the invention is only restricted by the appended patent claims.

1. A substrate processing apparatus, comprising:
a reaction chamber for accommodating one or more substrates for processing, wherein the reaction chamber walls comprise a first wall, second wall located opposite to the first wall, and one or more side walls connecting the first wall and the second wall;
an injection manifold attached to the first wall to feed precursor flow to the reaction chamber through an entrance opening in the first wall; and
two exhaust ports, a first exhaust port and a second exhaust port, arranged to at least one of the one or more side walls to remove fluid from the reaction chamber.

2. (canceled)

3. The apparatus of claim 1, wherein the two exhaust ports are configured to extend at least partially across the one or more side walls to which the exhaust ports are arranged.

4. (canceled)

5. (canceled)

6. The apparatus of claim 1, wherein the first exhaust port is arranged to a first side wall, and the second exhaust port is arranged to a second side wall, wherein the first side wall and the second side wall are opposite to each other and located at opposite sides of the reaction chamber.

7. The apparatus of claim 1, wherein the two exhaust ports are arranged adjacent to each other at one of the one or more side walls.

8. (canceled)

9. The apparatus of claim 1, wherein the two exhaust ports comprise a perforated structure.

10. The apparatus of claim 1, wherein the entrance opening is configured to extend across the first wall in a predetermined direction to a dimension of the reaction chamber.

11-27. (canceled)

28. A method for processing substrates, comprising:
accommodating one or more substrates within a reaction chamber, reaction chamber walls comprising a first wall, second wall located opposite to the first wall, and one or more side walls connecting the first wall and the second wall;
feeding precursor flow to the reaction chamber for substrate processing by an injection manifold through an entrance opening in the first wall; and
removing fluid from the reaction chamber through two exhaust ports, first exhaust port and second exhaust port, arranged to at least one of the one or more side walls.

29. The method of claim 28, wherein the first exhaust port is arranged to a first side wall, and the second exhaust port is arranged to a second side wall, wherein the first side wall and the second side wall are opposite to each other and located at opposite sides of the reaction chamber.

30. The method of claim 28, wherein the two exhaust ports are arranged adjacent to each other at one of the one or more side walls.

31. (canceled)

32. The method of claim 28, further comprising:
receiving first fluid flow and second fluid flow to the injection manifold and combining the first fluid flow and second fluid flow within the injection manifold to form the precursor flow.

33. The method of claim 32, comprising:
expanding the first fluid flow and the second fluid flow within the injection manifold to a dimension of the entrance opening extending across the first wall of the reaction chamber before combining said flows to form the precursor flow.

34-42. (canceled)

43. The apparatus of claim 1, configured to accommodate one or more stacks of substrates within the reaction chamber.

44. The apparatus of claim 1, wherein the injection manifold comprises a first expansion region and second expansion region configured to receive first fluid flow and second fluid flow, respectively, to the injection manifold.

45. The apparatus of claim 44, wherein the injection manifold is configured to combine the first fluid flow and the second fluid flow within the injection manifold to form the precursor flow.

46. The apparatus of claim 44, wherein the first expansion region and the second expansion region are configured to direct the first fluid flow and the second fluid flow, respectively, to propagate substantially towards each other before forming the precursor flow.

47. The apparatus of claim 44, wherein the first and second expansion regions are configured to expand the first fluid flow and the second fluid flow, respectively, within the injection manifold to a dimension of the entrance opening extending across the first wall of the reaction chamber before forming the precursor flow.

48. The apparatus of claim 1, comprising two injection manifolds, a first injection manifold and a second injection manifold, to feed precursor flow to the reaction chamber.

49. The apparatus of claim 48, wherein first injection manifold is attached to the first wall and a second injection manifold is attached to the second wall located opposite to the first injection manifold and the first wall.

50. The method of claim 28, comprising:
providing two injection manifolds, a first injection manifold and a second injection manifold, wherein the first injection manifold is attached to the first wall and the second injection manifold is attached to the second wall located opposite to the first injection manifold and the first wall; and
feeding precursor flow the reaction chamber by the two injection manifolds.

51. The method of claim 28, wherein accommodating the one or more substrates comprises: accommodating one or more stacks of substrates within the reaction chamber.
